(19) United States
(12) Patent Application Publication
(10) Pub. No.: US 2012/0120735 A1
(43) Pub. Date: May 17, 2012

(54) SEMICONDUCTOR DEVICE HAVING ELECTRICAL FUSE AND CONTROL METHOD THEREOF

(75) Inventors: Shuichi KUBOUCHI, Tokyo (JP); Daiki NAKASHIMA, Tokyo (JP)

(73) Assignee: ELPIDA MEMORY, INC., Tokyo (JP)

(21) Appl. No.: 13/297,960

(22) Filed: Nov. 16, 2011

(30) Foreign Application Priority Data
Nov. 17, 2010 (JP) 2010-257161

(51) Int. Cl. G11C 7/10; G11C 29/00; G11C 7/00

(52) U.S. Cl. 365/189.05; 365/189.07; 365/200

(57) ABSTRACT

To provide a plurality of fuse elements, each of which is either in a programmed state or a non-programmed state, a plurality of fuse determination circuits, each of which outputs a determination result signal that corresponds to a programmed state or a non-programmed state of the fuse element, and a plurality of latch circuits that commonly receive a first timing signal, and each of which latches and outputs the determination result signal synchronously with the first timing signal.

### BACKGROUND OF THE INVENTION

1. Field of the Invention

The present invention relates to a semiconductor device and a control method thereof, and more particularly relates to a semiconductor device including an electrical fuse used for adjusting a level of a power-supply potential, relieving defective addresses, and the like and to a control method of the semiconductor device.

2. Description of Related Art

In a semiconductor device, a fuse element is used for adjusting various parameters (adjusting a level of an internal-power-supply potential or a delay amount in a delay circuit, for example), relieving defective addresses (row redundancy relief or column redundancy relief, for example), and the like. In order to program desired operating parameters or desired defective addresses, the fuse elements are brought into either a conductive state or a non-conductive state. With this configuration, adjustment of the parameters and relieving of defective addresses can be achieved.

Examples of the fuse element include an electrical fuse element that is made of a material mainly including copper, impurity-doped polysilicon or the like. The electrical fuse element is electrically conductive (a non-programmed state) at an initial state. The electrical fuse can be changed to a non-conductive state (a programmed state) by generating heat by passing an electric current into the electrical fuse element so as to disconnect it (see Japanese Patent Application Laid-open No. 2007-329196).

However, as described in Japanese Patent Application Laid-open No. 2007-329196, there are cases where, even when known electrical disconnection or programming is performed on electrical fuse elements, the disconnection is not made as intended. That is, although disconnection processing is performed on plural electrical fuse elements, not all of the electrical fuse elements on which the disconnection processing has been performed are sufficiently disconnected. Consequently, insufficient disconnection causes the electrical fuse elements not to be completely non-conductive, and thus at the time of reading, there is a problem that electrical fuse elements that are supposed to be in a non-conductive or programmed state are erroneously determined as conductive or non-programmed state.

Meanwhile, similarly to the electrical fuse element described in Japanese Patent Application Laid-open No. 2007-329196, there is known an anti-fuse element as a type of an electrical fuse element that uses electricity to change its state, which is conductive or non-conductive. Contrary to the electrical fuse element of Japanese Patent Application Laid-open No. 2007-329196, the anti-fuse element is an element that stores information by changing its state as a non-conductive or non-programmed state to a conductive or programmed state. Writing or programming of information into the anti-fuse element is performed by insulation breakdown due to application of a high voltage. In the case of the anti-fuse element, similarly to the case of the electrical fuse element described in Japanese Patent Application Laid-open No. 2007-329196, in a strict sense, the result of the programming differs in each of electrical fuse elements. That is, there are various results such as an electrical fuse element with a high conducting level (that is, its resistance is low), that with a low conducting level (that is, its resistance is high), or that having failed with conduction (its resistance is particularly high).

Information stored in the fuse element is read out by using a determining circuit for determining the state of the fuse element. In order to read out the information by determining whether the fuse element is in a programmed state or a non-programmed state, it is necessary to provide a control circuit that controls the determining circuit. It is preferable to use internal power supply having a constant power-supply level, rather than using external power supply having a non-constant power supply level, for operating the control circuit. The reason that the level of external power supply is non-constant is that, due to the specifications thereof, there is a certain allowable range, such as 1.425 volts (V) to 1.575 V. On the other hand, because internal power supply uses a so-called bandgap circuit as a reference, its level is substantially constant regardless of the level of the external power supply. However, because it is configured that the level of the internal power supply is adjustable by using the fuse element as described above, even in anti-fuse elements in a programmed state or a conductive state, there exist anti-fuse elements with a high conducting level (that is, its resistance is low) and those with a low conducting level (that is, its resistance is high) in a mixed manner. That is, a difference in a determination time exists among a plurality of fuse elements. The level of the internal power supply is varied at each time the determination of respective fuse elements is completed.

If the level of the internal power supply can be adjusted in sixteen steps, a binary code having four-bit configuration is necessary. In this case, each of four bits constituting the binary code may be settled at respective timing during the determination of fuse elements. To give an extreme example, it is assumed that the level at an initial state is preset as a binary code “1000”, which is a central value of the level of the internal power supply. In this state, if the target adjustment level is a binary code “0111”, when a determination of the second fuse element is completed first, the binary code is changed to “1100”. The level of the internal power supply becomes therefore excessively high from the viewpoint of a device characteristic of the semiconductor device. In this case, in a so-called peripheral circuit excluding a fuse controlling part that uses the internal power supply, any ordinary operation cannot be performed at the time point where the binary code is “1100”. There is no problem as far as the peripheral circuit starts to operate after determinations of other fuse elements are finally completed and the binary code is settled as “0111”. However, this can cause a problem in the fuse controlling part that uses the internal power supply to determine the programming state of a fuse. Specifically, when the level of the internal power supply is varied, there is assumed a case that the determination time of the programming state becomes too short (or too long according to the combination of logics) resulting in failing the determination.

The present invention provides a semiconductor device including a plurality of electrical fuses in various conductive states and being capable of reading a programmed result by the electrical fuses without any erroneous determination, and a control method of the semiconductor device.

### SUMMARY

In one embodiment, there is provided a semiconductor device that includes: a first fuse circuit including a first fuse element, a second fuse element, and a first output circuit coupled in common to the first and second fuse elements, the first output circuit outputting a first signal which takes a first logic level when at least one of the first and second fuse elements takes a programmed state and a second logic level when both of the first and second fuse elements take an unprogrammed states; an internal power supply generating circuit generating an internal voltage that takes an adjusted level by a logic level of the first signal; a second fuse circuit including a third fuse element and a second output circuit coupled to the third fuse element, the second output circuit outputting a second signal which takes the first logic level when the third fuse element takes a programmed state and the second logic level when the third fuse element takes an unprogrammed state; and an address comparing circuit comparing in logic level the second signal with an address signal.

In another embodiment, there is provided a semiconductor device that includes first and second fuse determination circuits generate first and second determination result signals, respectively, a first latch circuit that latches and outputs the first determination result signal in response to a first timing signal, and a second latch circuit that latches and outputs the second determination result signal in response to a second timing signal that is generated after the first timing signal.

In one embodiment, there is provided a control method of a semiconductor device that includes performing a first fuse determining operation of outputting a first fuse code that decides a level of an internal-power-supply potential in response to a command signal, and performing a second fuse determining operation of outputting a second fuse code that indicates an address of a defective memory cell after performing the first fuse determining operation.

### BRIEF DESCRIPTION OF THE DRAWINGS

FIG. 1 is a block diagram indicative of a configuration of a semiconductor device 10 according to first to third embodiments of the present invention;

FIG. 2 is a circuit diagram indicative of a configuration of an anti-fuse set 92 and a latch circuit 93 for one bit, the anti-fuse set 92 and the latch circuit 93 being included in a predetermined anti-fuse circuit 94 shown in FIG. 1;

FIG. 3 is a circuit diagram for explaining the first embodiment of the present invention and showing a circuit configuration of a circuit part 90A that corresponds to a circuit part 90 encircled by a dashed dotted line in FIG. 1;

FIG. 4 is a timing diagram for explaining operations of the anti-fuse set 92 and the latch circuit 93 shown in FIG. 2, in a case where the circuit part 90A shown in FIG. 3 is used as the circuit part 90 shown in FIG. 1;

FIG. 5 is a block diagram for explaining the second embodiment of the present invention and showing a circuit configuration of a circuit part 90B that corresponds to the circuit part 90 encircled by the dashed dotted line in FIG. 1;

FIG. 6 is a timing diagram for explaining operations of the anti-fuse set 92 and the latch circuit 93 shown in FIG. 2, in a case where the circuit part 90B shown in FIG. 5 is used as the circuit part 90 shown in FIG. 1;

FIG. 7 is a block diagram for explaining the third embodiment of the present invention and showing a circuit configuration of a circuit part 90C that corresponds to the circuit part 90 encircled by the dashed dotted line in FIG. 1;

FIG. 8 is a block diagram indicative of a configuration of a semiconductor device 100 according to fourth and fifth embodiments of the present invention;

FIG. 9 is a circuit diagram for explaining the fourth embodiment of the present invention and showing a circuit configuration of a circuit part 900D that corresponds to a circuit part 900 encircled by the dashed dotted line in FIG. 8; and

FIG. 10 is a circuit diagram for explaining the fifth embodiment of the present invention and showing a circuit configuration of a circuit part 900E that corresponds to the circuit part 900 encircled by the dashed dotted line in FIG. 8.

### DETAILED DESCRIPTION OF THE EMBODIMENTS

Preferred embodiments of the present invention will be explained below in detail with reference to the accompanying drawings.

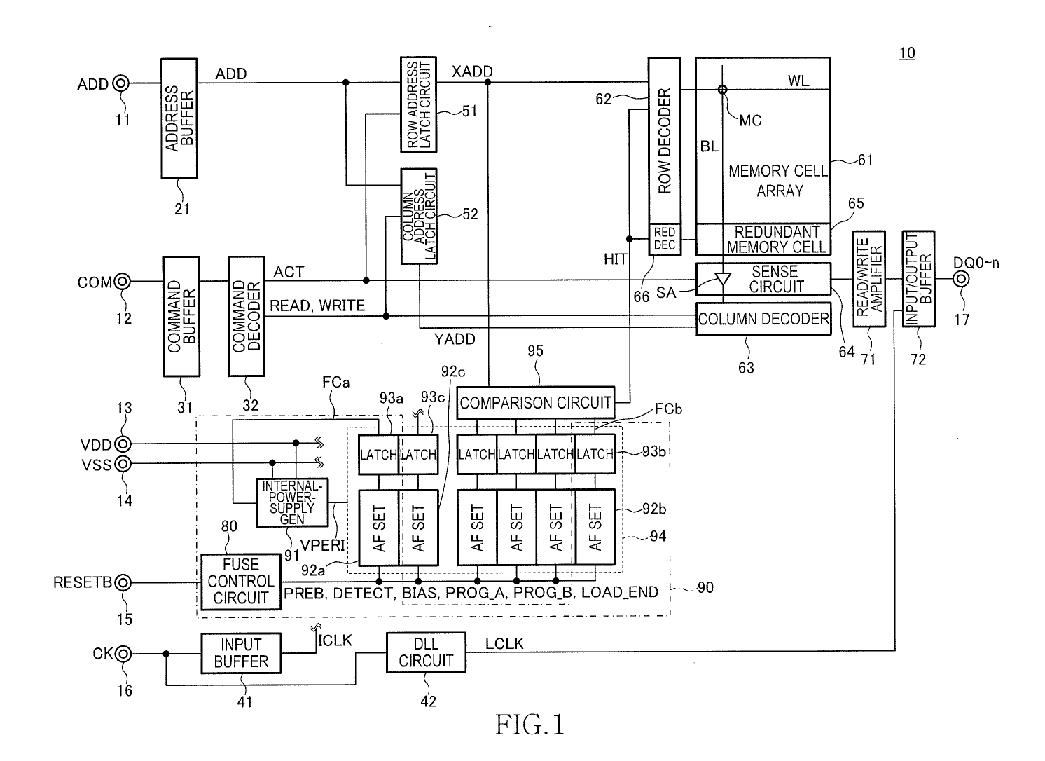

Referring now to FIG. 1, the semiconductor device 10 according to the present embodiment is a DRAM that is integrated in a single semiconductor chip. As external terminals of the semiconductor device 10, an address terminal 11, a command terminal 12, power-supply terminals 13 and 14, a reset terminal 15, a clock terminal 16, and a data input/output terminal 17 are provided. While other terminals such as a data strobe terminal are provided in the semiconductor device 10, these are omitted from the drawings.

The address terminal 11 is supplied with an address signal ADD. The address signal ADD is supplied to an address buffer 21. The output signal ADD from the address buffer 21 is supplied to a row address latch circuit 51 and a column address latch circuit 52. Among address signals ADD latched by the row address latch circuit 51, a row address XADD is supplied to a row decoder 62, and a column address YADD is supplied to a column decoder 63.

The command terminal 12 is supplied with command signals COM including a row-address strobe signal RAS, a column-address strobe signal CAS, a write enable signal WE, and a chip select signal CS. These command signals COM are supplied to a command buffer 31. These command signals COM supplied to the command buffer 31 are then supplied to a command decoder 32. The command decoder 32 is a circuit that generates various types of internal commands such as ACT, READ, and WRITE by holding, decoding, and counting these command signals. The generated command signals are supplied to the row address latch circuit 51, the column address latch circuit 52, and the column decoder 63.

The power-supply terminals 13 and 14 are supplied with a power-supply potential VDD and a ground potential VSS, respectively. The power-supply potential VDD and the ground potential VSS supplied to these power-supply terminals are then supplied to an internal-power-supply generating circuit 91, and the internal-power-supply generating circuit 91 generates an internal-power-supply potential VPERI.

The reset terminal 15 is supplied with a reset signal RESETB, which is activated at the time of turning the power on. The reset signal RESETB as a command signal for performing a fuse determining operation is supplied to a fuse control circuit 80.

The clock terminal 16 is supplied with an external clock signal CK. The external clock signal CK supplied to the clock terminal 16 is then supplied to an input buffer 41 and a DLL circuit 42. The input buffer 41 generates an internal clock signal ICLK upon reception of the external clock signal CK. The DLL circuit 42 generates an internal clock signal LCLK, and the generated internal clock signal LCLK is supplied to an input/output buffer 72.

The data input/output terminal 17 is a terminal that outputs read data DQ0 to DQn and inputs write data DQ0 to DQn, and is connected to the input/output buffer 72. The input/output buffer 72 outputs read data synchronously with the internal clock signal LCLK at the time of a reading operation.

The row decoder 62 selects any of word lines WL included in a memory cell array 61 based on the row address XADD. A plurality of the word lines WL and a plurality of bit lines BL are intersecting each other in the memory cell array 61, and memory cells MC are arranged at each of the intersections (only one word line WL, one bit line BL, and one memory cell MC are shown in FIG. 1). The bit line BL is connected to a corresponding sense amplifier SA in a sense circuit 64.

The column address YADD is supplied to the column decoder 63. The column decoder 63 selects any of the sense amplifiers SA included in the sense circuit 64 based on the column address YADD. The sense amplifier SA selected by the column decoder 63 is connected to a read/write amplifier 71. The read/write amplifier 71 further amplifies read data amplified by the sense amplifier SA at the time of a reading operation, and the further amplified read data is supplied to the input/output buffer 72. On the other hand, at the time of a writing operation, write data supplied from the input/output buffer 72 is amplified and the amplified write data is supplied to the sense amplifier SA.

The fuse control circuit 80 supplies a precharge signal PREB, a detection signal DETECT, a bias potential BIAS, and program signals PROG_A and PROG_B to each anti-fuse set (hereinafter, also “fuse determination circuit”) 92 upon reception of the reset signal RESETB. Furthermore, the fuse control circuit 80 generates a timing signal LOAD_END that is supplied to each latch circuit 93. Details of the fuse control circuit 80 are explained later.

An anti-fuse circuit 94 is constituted by a plurality of the anti-fuse sets (AF sets) 92, each of which includes a plurality of anti-fuse elements, and a plurality of the latch circuits 93, each of which includes a plurality of latch circuits. The internal-power-supply potential VPERI generated by the internal-power-supply generating circuit 91 is supplied to the anti-fuse circuit 94.

Among the anti-fuse circuits 94, the anti-fuse circuit 94 shown on the leftmost side of FIG. 1 is an anti-fuse circuit for internal-power-supply adjustment. This anti-fuse circuit 94 includes an anti-fuse set 92a and a latch circuit 93a, and an output thereof is input to the internal-power-supply generating circuit 91. Furthermore, among the anti-fuse circuits 94, the anti-fuse circuit 94 that is shown on the right side of FIG. 1, that includes anti-fuse sets 92b and latch circuits 93b, and that is connected to a comparison circuit 95 is an anti-fuse circuit 94 for relieving row addresses. In addition, the anti-fuse circuit 94 that is shown second from the left side of FIG. 1 is an anti-fuse circuit for adjusting other functions, and this anti-fuse circuit 94 includes an anti-fuse set 92c and a latch circuit 93c. Each of a plurality of fuse elements included in the anti-fuse sets 92a and 92c has an operating parameter of the semiconductor device 10 stored therein. Further, each of a plurality of fuse elements included in the anti-fuse sets 92b has an address of a defective memory cell included in the memory cell array 61 stored therein.

The anti-fuse circuit 94 reads whether an anti-fuse element included in each of the anti-fuse sets 92 is programmed or not, based on the detection signal DETECT generated from the fuse control circuit 80 having received the reset signal RESETS, which is activated at the time of turning the power on, and the read result is held in each of the latch circuits 93. Details of the anti-fuse circuit 94 are explained later.

In the comparison circuit 95, each piece of information held in each of the latch circuits 93 is respectively compared with each bit of the row address XADD, and a hit signal HIT is activated when there is a match between the information and the bit. Thereafter, based on the hit signal HIT, a redundant row decoder 66 is operated simultaneously with stopping of an operation of the row decoder 62 corresponding to a matched row address, and a redundant memory cell 65 is selected. On the other hand, when there is no match between the information and the bit, the hit signal HIT is not activated, and thus an operation of the row decoder 62 corresponding to the row address is performed, and the redundant row decoder 66 is not operated. In this manner, a normal cell with a defect is replaced by a redundant cell.

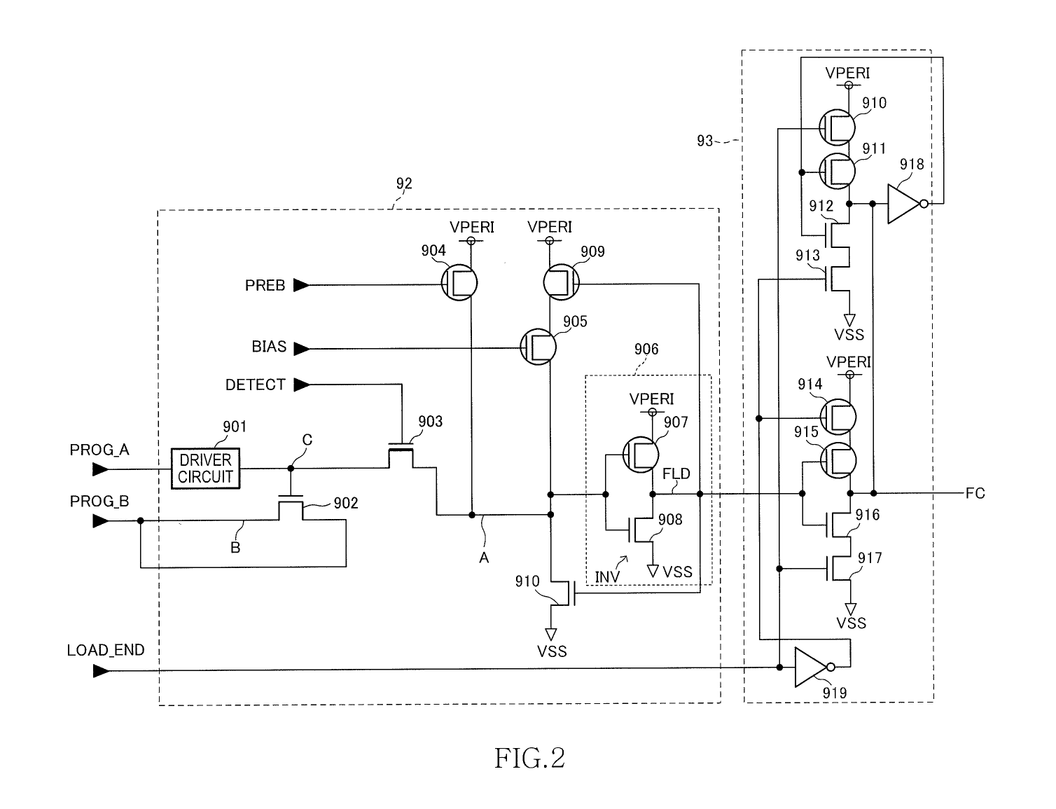

Turning to FIG. 2, the anti-fuse set 92 for one bit is configured to include a driver circuit 901, a transistor anti-fuse element 902, a selective transistor (an N-type transistor including a thick gate dielectric film) 903, a precharge transistor (a P-type transistor) 904, a bias transistor (a P-type transistor) 905, and a detection circuit 906. The first program signal PROG_A is input to the driver circuit 901. In the anti-fuse element 902, source and drain electrodes are connected to a node B to which the second program signal PROG_B is supplied, and a gate electrode is connected to anode C to which an output from the driver circuit 901 is supplied. The selective transistor 903 is connected between a detection node A and the gate electrode of the anti-fuse element 902, and the detection signal DETECT is input to the gate electrode. The precharge transistor 904 is connected between the internal-power-supply potential VPERI and the detection node A, and the precharge signal PREB is input to a gate electrode. In the bias transistor 905, the bias potential BIAS is input to a gate electrode. The detection circuit 906 detects the potential of the detection node A.

The detection circuit 906 includes an inverter INV that is connected between the internal-power-supply potential VPERI and the ground potential VSS. The inverter INV is constituted by a P-type transistor 907 and an N-type transistor 908 which are connected in series. An input node of the inverter INV is connected to the detection node A, and a determination result signal FLD is output from an output node of the inverter INV according to the potential of the detection node A.

The anti-fuse set 92 further includes a feedback transistor 909 (a P-type transistor) which is connected between the internal-power-supply potential VPERI (a power-supply line) and the bias transistor 905 and a discharge transistor 910 (an N-type transistor) which is connected between the detection node A and the ground potential VSS. The determination result signal FLD is input to a gate electrode of the feedback transistor 909 and a gate electrode of the discharge transistor 910.

In order to program the anti-fuse element 902 in the anti-fuse set 92 with the above configuration, the first program signal PROG_A is set to a high voltage, and the second program signal PROG_B is set to a low voltage. With this setting, a gate dielectric film of the anti-fuse element 902 is broken-down, thereby the node B and the node C are electrically connected (short-circuited), and thus the anti-fuse element 902 is in a programmed state.

Furthermore, as shown in FIG. 2, the latch circuit 93 for one bit is configured to include P-type transistors 910 and 911 and N-type transistors 912 and 913 that are serially connected between the internal-power-supply potential VPERI and the ground potential VSS, P-type transistors 914 and 915 and N-type transistors 916 and 917 that are also serially connected between the internal-power-supply potential VPERI and the ground potential VSS, and inverters 918 and 919.

Gate electrodes of the P-type transistor 910 and of the N-type transistor 917 are commonly connected and receive the timing signal LOAD_END. Gate electrodes of the N-type transistor 913 and of the P-type transistor 914 are commonly connected and receive an inversion signal of the timing signal LOAD_END that is an output from the inverter 919. Gate electrodes of the P-type transistor 915 and of the N-type transistor 916 are commonly connected and receive the determination result signal FLD that is an output from the detection circuit 906. Source electrodes of the P-type transistor 915 and of the N-type transistor 916 are also commonly connected. Gate electrodes of the P-type transistor 911 and of the N-type transistor 912 are commonly connected and receive an output from the inverter 918. Furthermore, source electrodes of the P-type transistor 911 and of the N-type transistor 912 are commonly connected and these are also commonly connected to the source electrodes of the P-type transistor 915 and of the N-type transistor 916. From the connecting points, a fuse code FC is output as an output of the latch circuit 93. With this configuration, when the timing signal LOAD_END is activated to a high level, the latch circuit 93 latches the determination result signal FLD and output the latched signal as the fuse code FC.

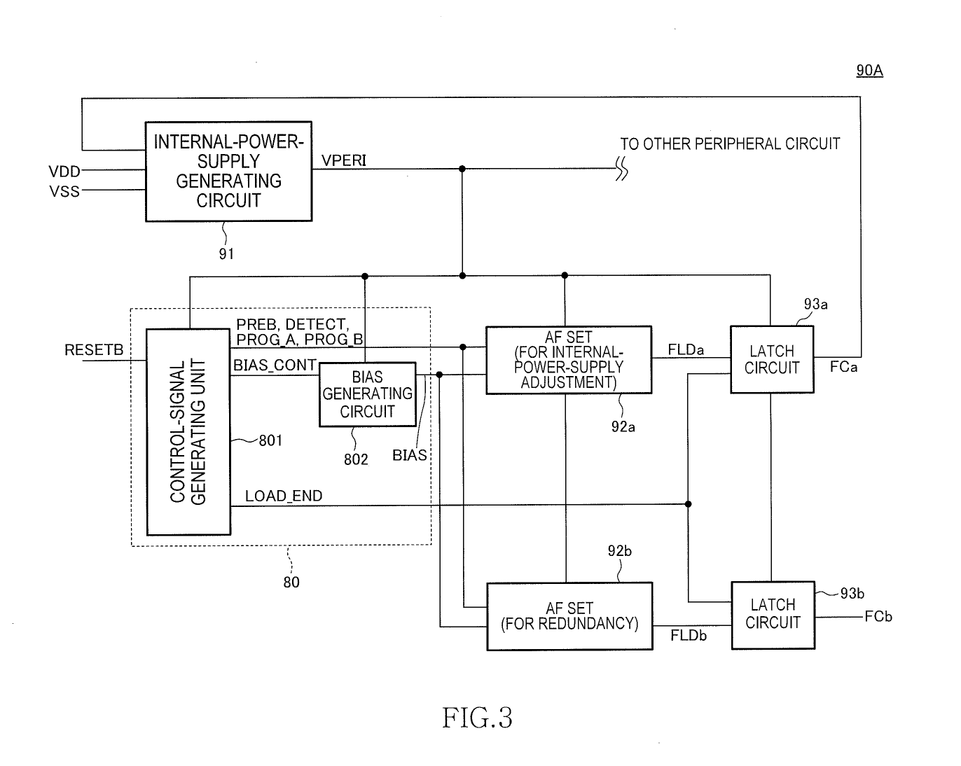

Turning to FIG. 3, the circuit part 90A includes the fuse control circuit 80, the internal-power-supply generating circuit 91, the anti-fuse set 92a for internal-power-supply adjustment, the latch circuit 93a, the anti-fuse set 92b for redundancy, and the latch circuit 93b. The internal-power-supply potential VPERI generated from the internal-power-supply generating circuit 91 is supplied to each of the fuse control circuit 80, the anti-fuse set 92a for internal-power-supply adjustment, the latch circuit 93a, the anti-fuse set 92b for redundancy, and the latch circuit 93b. The internal-power-supply potential VPERI is preset as a predetermined potential, for example, a potential corresponding to a binary code “1000”.

The fuse control circuit 80 is configured to include a control-signal generating unit 801 and a bias generating circuit 802.

The control-signal generating unit 801 generates the precharge signal PREB, the detection signal DETECT, the program signals PROG_A and PROG_B, and a bias control signal BIAS_CONT upon reception of the reset signal RESETB. The bias control signal BIAS_CONT is supplied to the bias generating circuit 802, and the bias generating circuit 802 generates the bias potential BIAS. The control-signal generating unit 801 also generates the timing signal LOAD_END.

Both the anti-fuse set 92a for internal-power-supply adjustment and the anti-fuse set 92b for redundancy receive the precharge signal PREB output from the fuse control circuit 80, the detection signal DETECT, the program signals PROG_A and PROG_B, and the bias potential BIAS, and then they respectively output a determination result signal FLDa and a determination result signal FLDb, according to the programmed state of the anti-fuse element in each of the anti-fuse sets 92a and 92b.

The latch circuits 93a and 93b commonly receive the timing signal LOAD_END output from the control-signal generating unit 801, respectively latch the determination result signals FLDa and FLDb synchronously with the timing signal LOAD_END, and respectively output the latched signals as a fuse code FCa and a fuse code FCb. The fuse code FCa is input to the internal-power-supply generating circuit 91, thereby settling the potential of the internal-power-supply potential VPERI. In addition, the fuse code FCb is input to the comparison circuit 95.

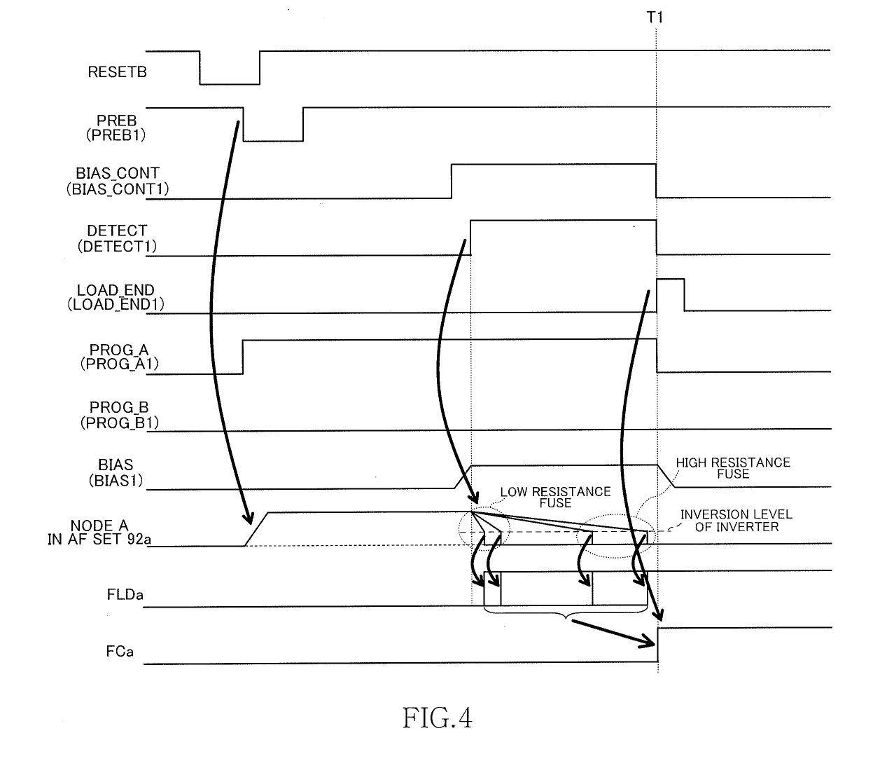

Next, with reference to a timing diagram of FIG. 4, there is explained a fuse determining operation of the anti-fuse circuit 94 in a case where the circuit part 90A shown in FIG. 3 is used as the circuit part 90 shown in FIG. 1. Note that in FIG. 4, only signals related to the anti-fuse set 92a are shown, and signals related to the anti-fuse set 92b are omitted because these signals are identical to those of the anti-fuse set 92a. Furthermore, in FIG. 4, only operations related to the anti-fuse element 902 of a programmed state (insulation broken-down) among the plural bits within the anti-fuse sets 92a are shown, and operations related to that of a non-programmed state (not insulation broken-down) are omitted.

First, the precharge signal PREB is activated to a low level for a predetermined period of time by activating the reset signal RESETB to a low level. By this activation, the precharge transistor 904 is turned on, and the detection node A is precharged to a VPERI level (a high level). After turning off the precharge transistor 904, the level of the bias voltage BIAS is increased according to the bias control signal BIAS_CONT. Thereafter, the detection signal DETECT is activated as a high level. At this time, the driver circuit 901 is in an off-state, and the second program signal PROG_B is equal to the ground potential VSS.

In this state, when the anti-fuse element 902 is programmed, a current path is formed between the node B that is equal to the ground potential VSS and the feedback transistor 909, via the bias transistor 905 and the selective transistor 903. At this time, the level of the detection node A to which the anti-fuse element 902 with a high conducting level (that is, its resistance is low) is connected is smoothly reduced to a low level, and this level quickly becomes lower than an inversion level of the inverter INV of the detection circuit 906. Consequently, the determination result signal FLDa, which is an output of the detection circuit 906, becomes a high level. In this manner, because a gate electrode of the feedback transistor 909 becomes a high level, the feedback transistor 909 becomes an off-state, and the supply of a current to the detection node A is stopped. Furthermore, because the discharge transistor 910 becomes an on-state, the potential of the detection node A is reduced to the ground potential VSS. Accordingly, thereafter, in the anti-fuse set 92a having the anti-fuse element 902 with a high conducting level (that is, its resistance is low), the determination result signal FLDa of a high level is kept to be output.

However, at this stage, the timing signal LOAD_END is in a deactivated state. Therefore, the determination result signal FLDa of a high level is not latched by the latch circuit 93a, and the fuse code FCa as an output of the latch circuit 93a is kept at a low level.

Thereafter, as time elapses, the level of the detection node A to which the anti-fuse element 902 with a low conducting level (that is, its resistance is high) is connected is reduced to a low level, and as the level of the detection node A becomes lower than the inversion level of the inverter INV of the detection circuit 906, the determination result signal FLDa, which is an output of the detection circuit 906, becomes a high level. Consequently, similarly to the case of the anti-fuse element 902 with a high conducting level (that is, its resistance is low) described above, the potential of the detection node A is reduced to the ground potential VSS. Thereafter, even in the anti-fuse set 92a including the anti-fuse element 902 with a low conducting level (that is, its resistance is high), the determination result signal FLDa of a high level is kept to be output.

Subsequently, after all of the anti-fuse sets 92a including the programmed anti-fuse element 902 have output the determination result signal FLDa of a high level and after a predetermined determination time has elapsed, the timing signal LOAD_END is activated. With this activation, all of the determination result signals FLDa are simultaneously latched by the latch circuit 93a, and the latched signals are output as the fuse code FCa at the same time. Thereafter, the fuse code FCa is input to the internal-power-supply generating circuit 91 and the potential of the internal-power-supply potential VPERI is settled. Furthermore, the fuse code FCb and the row address XADD are compared by the comparison circuit 95, and a defective cell is replaced to a redundant cell based on the comparison result.

As described above, according to the first embodiment, the fuse code FCa is not input to the internal-power-supply generating circuit 91 until when the determination result signal FLDa (readout result) of the anti-fuse set 92a including the anti-fuse element 902 with a low conducting level (that is, its resistance is high) is settled. Therefore, it is possible to avoid a case where the potential of the internal-power-supply potential VPERI becomes an unintended level during reading of the anti-fuse element 902. With this configuration, in other types of anti-fuse circuits using the internal-power-supply potential VPERI, such as an anti-fuse circuit for redundancy, no variation occurs in the internal-power-supply potential VPERI during reading of the anti-fuse element 902, and therefore it is possible to prevent occurrence of erroneous determinations.

The second embodiment of the present invention is explained next. In the first embodiment, reading of a fuse element is performed by using a preset internal-power-supply potential VPERI (such as a potential corresponding to a binary code “1000”, which is an intermediate level). However, when the semiconductor device to be operated actually requires the internal-power-supply potential VPERI corresponding to a binary code “0111”, because the binary code “1000” is used, it does not really satisfy the requirement of the semiconductor device. Therefore, in this case, an erroneous determination can be made depending on the conducting level of the fuse element.

To deal with this problem, in the second embodiment, a plurality (two) of anti-fuse sets for internal-power-supply adjustment are provided, and it is configured that erroneous determinations are not made as far as any one of the two anti-fuse sets is accurately programmed. When the probability of occurrence of an erroneous determination is assumed to be 1%, the probability of an erroneous determination occurring in both of the anti-fuse sets is 0.01%, and thus even if that case happens, it can be said that there is hardly any influence on the yield of the semiconductor device.

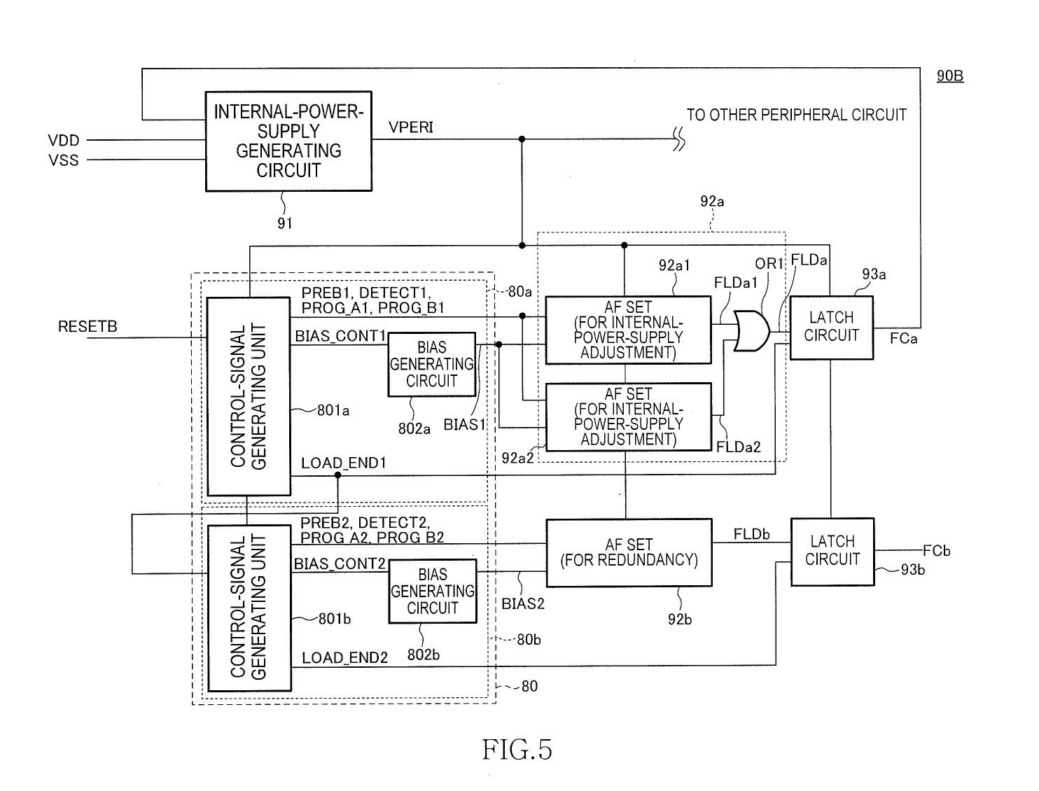

Turning to FIG. 5, the fuse control circuit 80 is constituted by a fuse control circuit 80a for internal-power-supply adjustment and a fuse control circuit 80b for redundancy. The fuse control circuit 80a is configured to include a control-signal generating unit 801a and a bias generating circuit 802a, and the fuse control circuit 80b is configured to include a control-signal generating unit 801b and a bias generating circuit 802b. Incidentally, in FIG. 5, constituent elements identical to those of the circuit part 90A shown in FIG. 3 are denoted by like reference numerals and redundant explanations thereof are omitted.

The control-signal generating unit 801a generates a precharge signal PREB1, a detection signal DETECT1, program signals PROG_A1 and PROG_B1, and a bias control signal BIAS_CONT1 upon reception of the reset signal RESETB. The bias control signal BIAS_CONT1 is supplied to the bias generating circuit 802a, and the bias generating circuit 802a generates a bias potential BIAS1. The control-signal generating unit 801a also generates a timing signal LOAD_END1.

The control-signal generating unit 801b generates a precharge signal PREB2, a detection signal DETECT2, program signals PROG_A2 and PROG_B2, and a bias control signal BIAS_CONT2 upon reception of the timing signal LOAD_END1. The bias control signal BIAS_CONT2 is supplied to the bias generating circuit 802b, and the bias generating circuit 802b generates a bias potential BIAS2. The control-signal generating unit 801b also generates a timing signal LOAD_END2.

The anti-fuse set 92a for internal-power-supply adjustment includes two anti-fuse sets 92a1 and 92a2. In this case, the anti-fuse sets 92a1 and 92a2 are programmed in the same manner. That is, an operating parameter indicating the same internal-power-supply potential level is stored in a plurality of fuse elements. The first and second anti-fuse sets 92a1 and 92a2 receive the precharge signal PREB1, the detection signal DETECT1, the program signals PROG_A1 and PROG_B1, and the bias potential BIAS1 that are output from the fuse control circuit 80a, and respectively output a determination result signal FLDa1 and a determination result signal FLDa2 according to the programmed state of the anti-fuse element in each of the anti-fuse sets 92a1 and 92a2. The determination result signals FLDa1 and FLDa2 are input to an OR circuit OR1, and an output from the OR circuit OR1 becomes the determination result signal FLDa of the anti-fuse set 92a. With this configuration, even if any one of the determination result signals FLDa1 and FLDa2 of the anti-fuse sets 92a1 and 92a2 is erroneously determined, it is possible to make the probability of occurrence of an erroneous determination of the determination result signal FLDa remarkably low. In the second embodiment, because the number of fuse elements for internal-power-supply adjustment is significantly smaller than the number of the fuse elements for redundancy, even when the anti-fuse set 92a for internal-power-supply adjustment is configured to include a plurality of anti-fuse sets, there is hardly any influence on the chip size of the semiconductor device.

The anti-fuse set 92b for redundancy receives the precharge signal PREB2, the detection signal DETECT2, the program signals PROG_A2 and PROG_B2, and the bias potential BIAS2 that are output from the fuse control circuit 80b, and outputs the determination result signal FLDb according to the programmed state of the anti-fuse element in the anti-fuse set 92b.

The latch circuit 93a responds to an input of the timing signal LOAD_END1 output from the control-signal generating unit 801a, and then latches the determination result signal FLDa and outputs the latched signal as the fuse code FCa. The fuse code FCa is input to the internal-power-supply generating circuit 91, thereby settling the potential of the internal-power-supply potential VPERI.

The latch circuit 93b responds to an input of the timing signal LOAD_END2 output from the control-signal generating unit 801b, and then latches the determination result signal FLDb and outputs the latched signal as the fuse code FCb. The fuse code FCb is input to the comparison circuit 95.

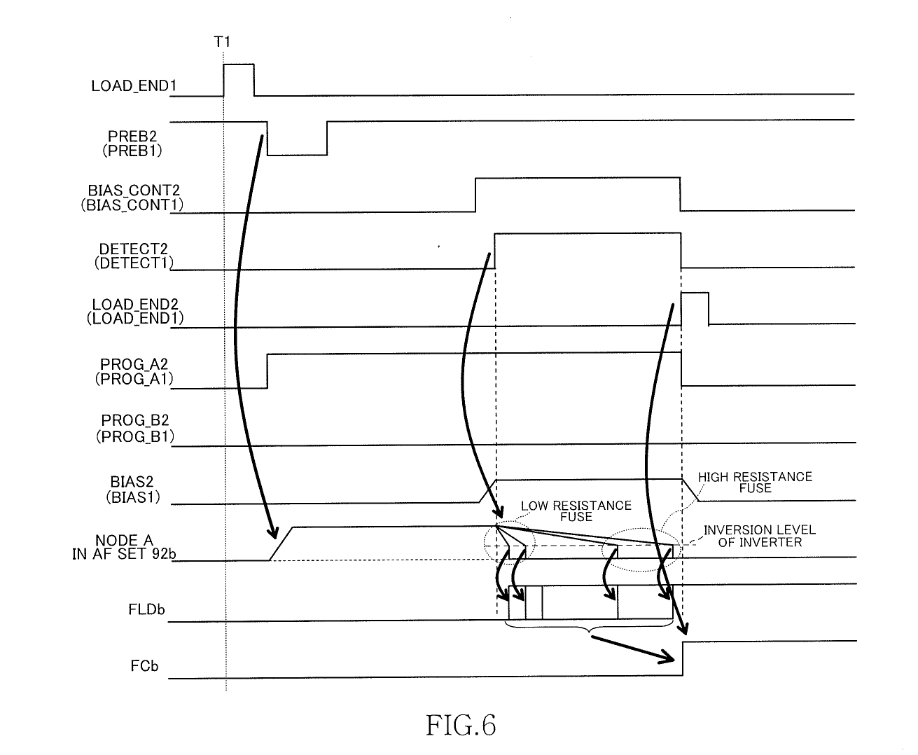

With reference to the timing diagrams of FIGS. 4 and 6, there is explained a fuse determining operation of the anti-fuse circuit 94 in a case where the circuit part 90B shown in FIG. 5 is used as the circuit part 90 shown in FIG. 1. In the following explanations, signal names (such as “PREB1”) denoted in parentheses in FIG. 4 correspond to signal names shown in FIG. 5. That is, in FIG. 4, signals related only to the anti-fuse set 92a for internal-power-supply adjustment are shown. As for signals related to the anti-fuse set 92b, illustrations thereof are omitted because these signals keep a deactivated level until a time T1. In FIG. 6, signals related only to the anti-fuse set 92b for redundancy are shown. As for signals related to the anti-fuse set 92a, illustrations thereof are omitted because these signals keep their level after the time T1 shown in FIG. 4. Similarly to FIG. 4, also in FIG. 6, only operations related to the anti-fuse element 902 of a programmed state (insulation broken-down) among the plural bits within the anti-fuse sets 92b are shown, and operations related to that of a non-programmed state (not insulation broken-down) are omitted.

A first fuse determining operation of reading an operating parameter stored in a plurality of fuse elements included in the anti-fuse set 92a by the fuse control circuit 80a, the anti-fuse set 92a, and the latch circuit 93a is performed first. Because the first fuse determining operation is identical to the fuse determining operation up to the time T1 shown in FIG. 4, explanations thereof will be omitted.

At the time T1, when the timing signal LOAD_END1 as an output of the control-signal generating unit 801a is activated, all of the determination result signals FLDa are simultaneously latched by the latch circuit 93a, and the latched signals are output as the fuse code FCa at the same time. With this configuration, the fuse code FCa is input to the internal-power-supply generating circuit 91 and the potential of the internal-power-supply potential VPERI is settled.

A second fuse determining operation of reading an operating parameter stored in a plurality of fuse elements included in the anti-fuse set 92b by the fuse control circuit 80b, the anti-fuse set 92b, and the latch circuit 93b is performed next. The second fuse determining operation is explained with reference to FIG. 6.

As shown in FIG. 6, after the internal-power-supply potential VPERI is settled, the timing signal LOAD_END1 is in a deactivated level. The timing signal LOAD_END1 is input to the control-signal generating unit 801b, and an operation related to the anti-fuse set 92b for redundancy using the internal-power-supply potential VPERI having its level settled is started. Operations afterwards are identical to the operations explained in the first embodiment. At the timing corresponding to the change of the potential of the node A in each of the anti-fuse sets 92b, the determination result signal FLDb of a high level is respectively output, and the timing signal LOAD_END2 is activated after a predetermined determination time has elapsed. Accordingly, all of the determination result signals FLDb are simultaneously latched by the latch circuit 93b, and the latched signals are output as the fuse code FCb at the same time. With this configuration, the fuse code FCb is input to the comparison circuit 95, the fuse code FCb and the row address XADD are compared, and a defective cell is replaced to a redundant cell based on the comparison result.

As described above, in the second embodiment, the level of the internal-power-supply potential VPERI is settled first, and then a determining operation of fuse elements in the anti-fuse set 92b for redundancy is performed after reflecting the settled internal-power-supply potential. With this configuration, it is possible to perform a determining operation of fuse elements for redundancy by using an internal potential that is originally supposed to be used for the semiconductor device 10, and thus erroneous determinations can be prevented.

The third embodiment of the present invention is explained next. While the fuse control circuit 80a for internal power supply adjustment and the fuse control circuit 80b for redundancy are separately provided in the second embodiment, the third embodiment explains an example where these circuits are shared.

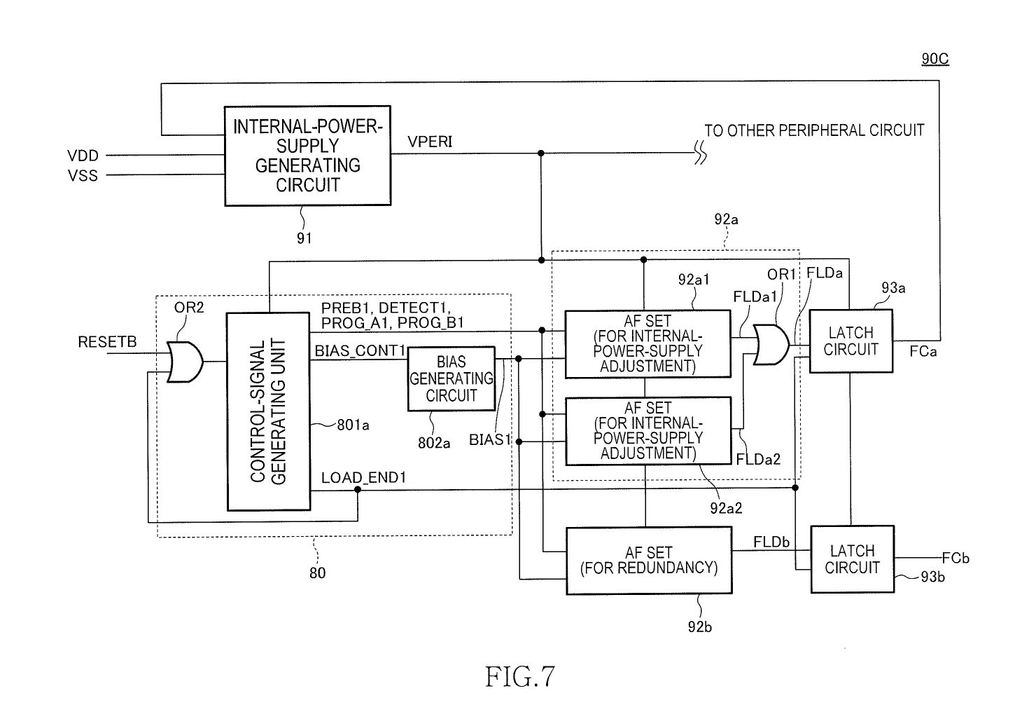

The fuse control circuit 80 is configured to include the control-signal generating unit 801a, the bias generating circuit 802a, and an OR circuit OR2. Incidentally, in FIG. 7, constituent elements identical to those of the circuit part 90B shown in FIG. 5 are denoted by like reference numerals and redundant explanations thereof will be omitted.

The reset signal RESETB is input to the OR circuit OR2, and the control-signal generating unit 801a generates the precharge signal PREB1, the detection signal DETECT1, the program signals PROG_A1 and PROG_B1, and the bias control signal BIAS_CONT1 upon reception of an output of the OR circuit OR2. The bias control signal BIAS_CONT1 is supplied to the bias generating circuit 802a, and the bias generating circuit 802a generates the bias potential BIAS1. Furthermore, the control-signal generating unit 801a also generates the timing signal LOAD_END1. The timing signal LOAD_END1 is input to the latch circuits 93a and 93b and also input to the OR circuit OR2.

In a fuse determining operation performed by the anti-fuse circuit 94 in a case where the circuit part 90C shown in FIG. 7 is used as the circuit part 90 shown in FIG. 1, the operations shown in FIG. 4 and FIG. 6 are performed simultaneously (concurrently), and these are performed for twice. Because details of this fuse determining operation are identical to those of the operations shown in FIGS. 4 and 6, explanations thereof will be omitted. Note that signal names (such as “PREB1”) denoted in parentheses in FIGS. 4 and 6 correspond to signal names shown in FIG. 7. In addition, the timing signal LOAD_END1 shown at the topmost part of FIG. 6 does not exist in the third embodiment.

According to the third embodiment, two fuse control circuits provided in a separated manner in the second embodiment can be integrated as one circuit, and therefore the circuit size can be reduced.

Although a determination of anti-fuse sets for redundancy is also performed at the first fuse determining operation (for internal power supply adjustment), this causes no problem because the second fuse determining operation (for redundancy) securely performs a determination of anti-fuse sets that have not been determined at the first fuse determining operation. Furthermore, although a determination of anti-fuse sets for internal power supply adjustment is performed again at the second fuse determining operation (for redundancy), this causes no problem because only the same result as the already determined one is output again.

Fourth and fifth embodiments of the present invention are explained next. In the first to third embodiments, because the operating parameter for adjusting the internal-power-supply potential VPERI is different in each device, fuse sets for internal-power-supply adjustment are provided to adjust respective potentials. Due to the same reason, in a strict sense, the operating parameter for adjusting a bias generated by a bias generating circuit is also different in each device.

Therefore, the fourth embodiment explains a semiconductor device including a fuse set for adjusting a potential of the bias. Specifically, the fourth embodiment explains an example where an operating parameter indicating the level of a bias potential supplied to an anti-fuse set for redundancy is stored in a fuse set.

Furthermore, the fifth embodiment explains a semiconductor device including a fuse set for adjusting a detection time of a fuse. Specifically, the fifth embodiment explains an example where an operating parameter indicating a timing of supplying signals (the length of the detection time) to an anti-fuse set for redundancy is stored in a fuse set.

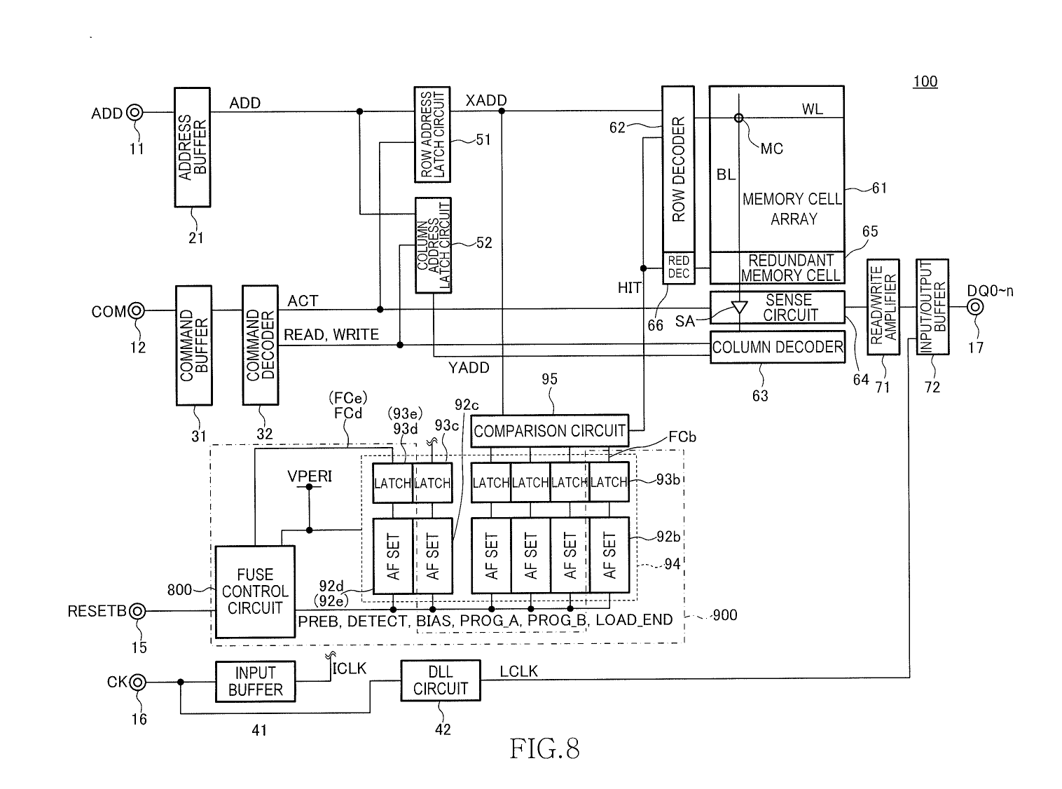

In the semiconductor device 100 shown in FIG. 8, as the difference to the semiconductor device 10 shown in FIG. 1, the power-supply terminals 13 and 14, the internal-power-supply generating circuit 91, and the anti-fuse circuit 94 constituted by the anti-fuse set 92a and the latch circuit 93a are omitted. In the semiconductor device 100, an anti-fuse set 92d for bias adjustment and a latch circuit 93d are provided, and a fuse control circuit 800 is provided instead of the fuse control circuit 80. Incidentally, in FIG. 8, constituent elements identical to those of the semiconductor device 10 shown in FIG. 1 are denoted by like reference numerals and redundant explanations thereof will be omitted.

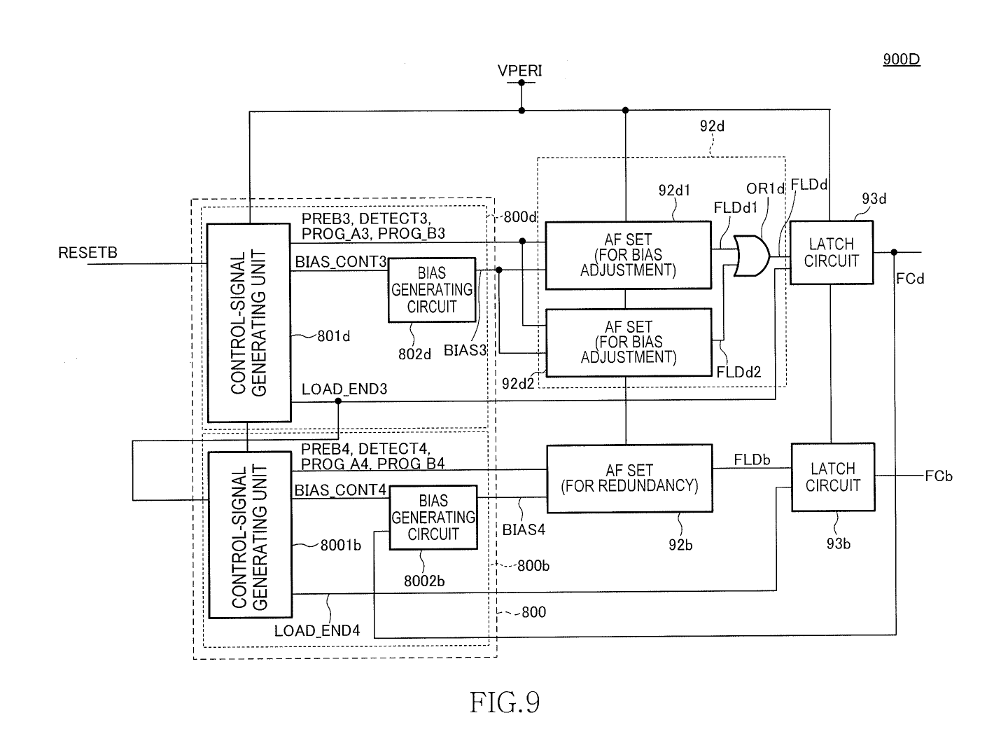

Turning to FIG. 9, the circuit part 900D includes the fuse control circuit 800, the anti-fuse set 92d for bias adjustment, the latch circuit 93d, the anti-fuse set 92b for redundancy, and the latch circuit 93b. The internal-power-supply potential VPERI is supplied to each of the fuse control circuit 800, the anti-fuse set 92d for bias adjustment, the latch circuit 93d, the anti-fuse set 92b for redundancy, and the latch circuit 93b.

The fuse control circuit 800 is constituted by a fuse control circuit 800d for bias adjustment and a fuse control circuit 800b for redundancy. The fuse control circuit 800d is configured to include a control-signal generating unit 801d and a bias generating circuit 802d, and the fuse control circuit 800b is configured to include a control-signal generating unit 8001b and a bias generating circuit 8002b.

The control-signal generating unit 801d generates a precharge signal PREB3, a detection signal DETECT3, program signals PROG_A3 and PROG_B3, and a bias control signal BIAS_CONT3 upon reception of the reset signal RESETB. The bias control signal BIAS_CONT3 is supplied to the bias generating circuit 802d, and the bias generating circuit 802d generates a bias potential BIAS3. The control-signal generating unit 801d also generates a timing signal LOAD_END3.

The control-signal generating unit 8001b generates a precharge signal PREB4, a detection signal DETECT4, program signals PROG_A4 and PROG_B4, and a bias control signal BIAS_CONT4 upon reception of the timing signal LOAD_END3. The bias control signal BIAS_CONT4 is supplied to the bias generating circuit 8002b, and the bias generating circuit 8002b generates a bias potential BIAS4. Furthermore, the control-signal generating unit 8001b also generates a timing signal LOAD_END4.

The anti-fuse set 92a for bias adjustment includes two anti-fuse sets 92d1 and 92d2. In this case, the anti-fuse sets 92d1 and 92d2 are programmed in the same manner. That is, an operating parameter indicating the same bias potential level is stored in a plurality of fuse elements. The first and second anti-fuse sets 92d1 and 92d2 receive the precharge signal PREB3, the detection signal DETECT3, the program signals PROG_A3 and PROG_B3, and the bias potential BIAS3 that are output from the fuse control circuit 800d, and respectively output a determination result signal FLDd1 and a determination result signal FLDd2 according to the programmed state of the anti-fuse element in each of the anti-fuse sets 92d1 and 92d2. The determination result signals FLDd1 and FLDd2 are input to an OR circuit OR1d, and an output from the OR circuit OR1d becomes a determination result signal FLDd of the anti-fuse set 92d. In this manner, because the anti-fuse set 92d is constituted by the two anti-fuse sets 92d1 and 92d2, the anti-fuse set 92d can also achieve the same effects as those of the anti-fuse set 92a for internal-power-supply adjustment described in the second embodiment.

The anti-fuse set 92b for redundancy receives the precharge signal PREB4, the detection signal DETECT4, the program signals PROG_A4 and PROG_B4, and the bias potential BIAS4 that are output from the fuse control circuit 800b, and outputs the determination result signal FLDb according to the programmed state of the anti-fuse element in the anti-fuse set 92b.

The latch circuit 93d responds to an input of the timing signal LOAD_END3 output from the control-signal generating unit 801d, and then latches the determination result signal FLDd and outputs the latched signal as a fuse code FCd. The fuse code FCd is input to the bias generating circuit 8002b, thereby settling the potential of the bias potential BIAS4 input to the anti-fuse set 92b for redundancy.

The latch circuit 93b responds to an input of the timing signal LOAD_END4 output from the control-signal generating unit 8001b, and then latches the determination result signal FLDb and outputs the latched signal as the fuse code FCb. The fuse code FCb is input to the comparison circuit 95.

As for a fuse determining operation of the anti-fuse circuit 94 in a case where the circuit part 900D shown in FIG. 9 is used as the circuit part 900 shown in FIG. 8, because it is similar to the operation described in the second embodiment, explanations thereof will be omitted.

As described above, in the fourth embodiment, the level of the bias potential BIAS4 supplied to anti-fuse sets for redundancy can be adjusted by the anti-fuse set 92d for bias adjustment.

The fifth embodiment of the present invention is explained next.

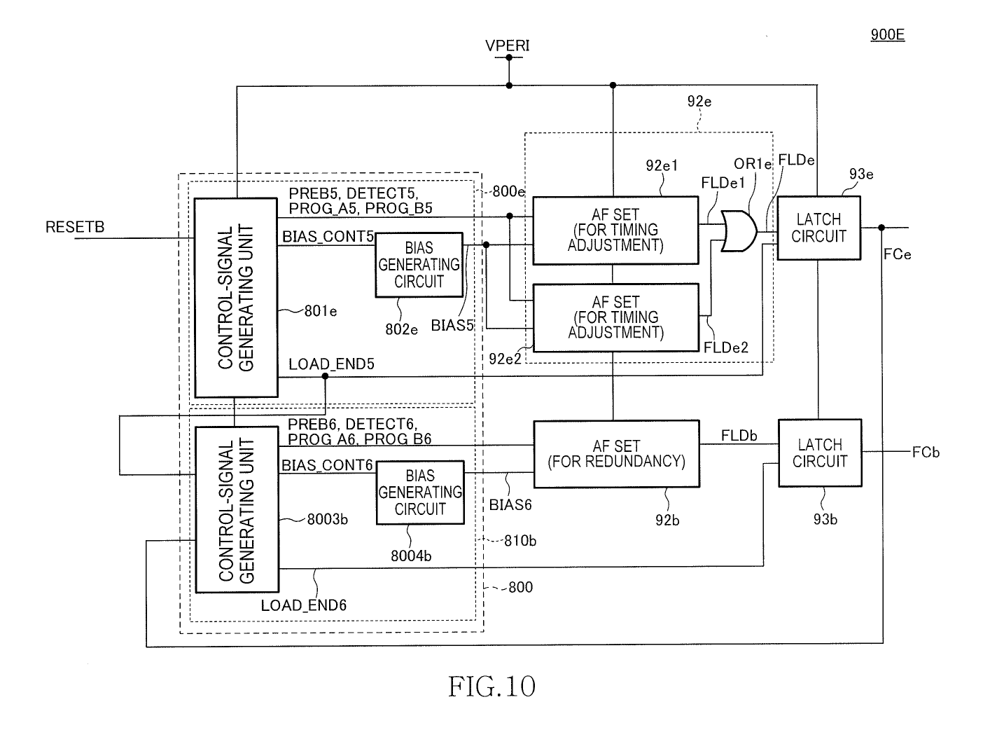

Turning to FIG. 10, the circuit part 900E includes the fuse control circuit 800, an anti-fuse set 92e for timing adjustment, a latch circuit 93e, the anti-fuse set 92b for redundancy, and the latch circuit 93b. The internal-power-supply potential VPERI is supplied to each of the fuse control circuit 800, the anti-fuse set 92e for timing adjustment, the latch circuit 93e, the anti-fuse set 92b for redundancy, and the latch circuit 93b.

The fuse control circuit 800 is constituted by a fuse control circuit 800e for timing adjustment and a fuse control circuit 810b for redundancy. The fuse control circuit 800e is configured to include a control-signal generating unit 801e and a bias generating circuit 802e, and the fuse control circuit 810b is configured to include a control-signal generating unit 8003b and a bias generating circuit 8004b.

The control-signal generating unit 801e generates a precharge signal PREB5, a detection signal DETECT5, program signals PROG_A5 and PROG_B5, and a bias control signal BIAS_CONT5 upon reception of the reset signal RESETB. The bias control signal BIAS_CONT5 is supplied to the bias generating circuit 802e, and the bias generating circuit 802e generates a bias potential BIAS5. The control-signal generating unit 801e also generates a timing signal LOAD_END5.

The control-signal generating unit 8003b generates a precharge signal PREB6, a detection signal DETECT6, program signals PROG_A6 and PROG_B6, and a bias control signal BIAS_CONT6 upon reception of the timing signal LOAD_END5. The bias control signal BIAS_CONT6 is supplied to the bias generating circuit 8004b, and the bias generating circuit 8004b generates a bias potential BIAS6. The control-signal generating unit 8003b also generates a timing signal LOAD_END6.

The anti-fuse set 92e for timing adjustment includes two anti-fuse sets 92e1 and 92e2. In this case, the anti-fuse sets 92e1 and 92e2 are programmed in the same manner. That is, the same operating parameter for timing adjustment is stored in a plurality of fuse elements. The first and second anti-fuse sets 92e1 and 92e2 receive the precharge signal PREB5, the detection signal DETECT5, the program signals PROG_A5 and PROG_B5, and the bias potential BIAS5 that are output from the fuse control circuit 800e, and respectively output a determination result signal FLDe1 and a determination result signal FLDe2 according to the programmed state of the anti-fuse element in each of the anti-fuse sets 92e1 and 92e2. The determination result signals FLDe1 and FLDe2 are input to an OR circuit OR1e, and an output from the OR circuit OR1e becomes a determination result signal FLDe of the anti-fuse set 92e. With this configuration, the anti-fuse set 92e can also achieve the same effects as those of the anti-fuse set 92a for internal-power-supply adjustment described in the second embodiment and of the anti-fuse set 92d for bias adjustment described in the fourth embodiment.

The anti-fuse set 92b for redundancy receives the precharge signal PREB6, the detection signal DETECT6, the program signals PROG_A6 and PROG_B6, and the bias potential BIAS6 that are output from the fuse control circuit 810b, and outputs the determination result signal FLDb according to the programmed state of the anti-fuse element in the anti-fuse set 92b.

The latch circuit 93e responds to an input of the timing signal LOAD_END5 output from the control-signal generating unit 801e, and then latches the determination result signal FLDe and outputs the latched signal as a fuse code FCe. The fuse code FCe is input to the control-signal generating circuit 8003b. Accordingly, each of the timings (the length of the detection time) of the bias control signal BIAS_CONT6, the detection signal DETECT6, and the timing signal LOAD_END6 is adjusted.

As for a fuse determining operation of the anti-fuse circuit 94 in a case where the circuit part 900E shown in FIG. 10 is used as the circuit part 900 shown in FIG. 8, similarly to the fifth embodiment, because it is similar to the operation described in the second embodiment, explanations thereof will be omitted.

As described above, according to the fifth embodiment, the timing (the length of the detection time) of respective signals input to the anti-fuse set 92b for redundancy, can be adjusted by the anti-fuse set 92e for timing adjustment.

It is apparent that the present invention is not limited to the above embodiments, but may be modified and changed without departing from the scope and spirit of the invention.

For example, in the third embodiment, a determining operation for internal power supply and a determining operation for redundancy are performed simultaneously for twice; however, it is also possible to configure such that the determining operation for internal power supply and the determining operation for redundancy are performed simultaneously only at the first fuse determining operation and only the determining operation for redundancy is performed at the second fuse determining operation.

In addition, an anti-fuse circuit for relieving row addresses, an anti-fuse circuit for power-supply adjustment, and an anti-fuse circuit for adjusting other functions have been exemplified as the anti-fuse circuit according to the present invention; however, in the present invention, it is also possible to provide an anti-fuse circuit for relieving column addresses and anti-fuse circuits for adjusting further other functions.

In addition, while not specifically claimed in the claim section, the applicant reserves the right to include in the claim section of the application at any appropriate time the following devices:

A1. A semiconductor device comprising:

a plurality of fuse elements each brought into a state of one of a programmed state and a non-programmed state;

a plurality of fuse determination circuits each outputting a determination result signal based on the state of an associated one of the fuse elements; and

a plurality of latch circuits that commonly receive a first timing signal, each of the latch circuits latching and outputting the determination result signal supplied from an associated one of the fuse determination circuits synchronously with the first timing signal.

A2. The semiconductor device as described in A1, further comprising a memory cell array that includes a plurality of memory cells, wherein

the fuse elements include a plurality of first fuse elements having an operating parameter of the semiconductor device stored therein, and a plurality of second fuse elements having an address of a defective memory cell included in the memory cell array stored therein, and

the latch circuits are allocated at least to the first fuse elements.

A3. The semiconductor device as described in A2, wherein the first fuse elements include first and second fuse sets having a same operating parameter stored therein.

A4. The semiconductor device as described in A3, wherein the operating parameter includes a parameter indicating a level of an internal-power-supply potential that is supplied at least to the fuse determination circuits.

A5. The semiconductor device as described in A4, wherein the fuse determination circuits allocated to the second fuse elements are activated after settling the level of the internal-power-supply potential by the operating parameter stored in the first fuse elements.

What is claimed is:

1. A semiconductor device comprising:
a first fuse circuit including a first fuse element, a second fuse element, and a first output circuit coupled in common to the first and second fuse elements, the first output circuit outputting a first signal which takes a first logic level when at least one of the first and second fuse elements takes a programmed state and a second logic level when both of the first and second fuse elements take an unprogrammed states;
an internal power supply generating circuit generating an internal voltage that takes an adjusted level by a logic level of the first signal;
a second fuse circuit including a third fuse element and a second output circuit coupled to the third fuse element, the second output circuit outputting a second signal which takes the first logic level when the third fuse element takes a programmed state and the second logic level when the third fuse element takes an unprogrammed state; and
an address comparing circuit comparing in logic level the second signal with an address signal.

2. The semiconductor device as claimed in claim 1, wherein the internal power supply generating circuit supplies the internal voltage to the second fuse circuit and the second output circuit of the second fuse circuit outputs the second signal by consuming the internal voltage.

3. The semiconductor device as claimed in claim 1, wherein the first fuse circuit starts to perform a detection whether each of the first and second fuse takes the programmed state or the unprogrammed state in response to a first control signal, and finishing the detection and outputting the first signal in response to a second control signal, the second fuse circuit starts to perform a detection whether the third fuse takes the programmed state or the unprogrammed state in response to the second control signal.

4. The semiconductor device as claimed in claim 3, wherein the internal power supply generating circuit supplies the internal voltage to the second fuse circuit and the detection of the second fuse circuit is performed by consuming the internal voltage.

5. The semiconductor device as claimed in claim 3, further comprising an external terminal receiving the first control signal from outside of the semiconductor device.

6. A semiconductor device comprising:
first and second fuse determination circuits generate first and second determination result signals, respectively;
a first latch circuit that latches and outputs the first determination result signal in response to a first timing signal; and
a second latch circuit that latches and outputs the second determination result signal in response to a second timing signal that is generated after the first timing signal.

7. The semiconductor device as claimed in claim 6, further comprising a memory cell array that includes a plurality of memory cells, wherein
the first determination result signal indicates an operating parameter of the semiconductor device, and
the second determination result signal indicates an address of a defective memory cell included in the memory cell array.

8. The semiconductor device as claimed in claim 7, wherein
the first timing signal is activated after settling a value of the first determination result signal, and
the second timing signal is activated after settling a value of the second determination result signal.

9. The semiconductor device as claimed in claim 7, wherein the operating parameter includes a parameter indicating a level of an internal-power-supply potential that is supplied at least to the second fuse determination circuit.

10. A control method of a semiconductor device comprising:
performing a first fuse determining operation of outputting a first fuse code that decides a level of an internal-power-supply potential in response to a command signal; and
performing a second fuse determining operation of outputting a second fuse code that indicates an address of a defective memory cell after performing the first fuse determining operation.

11. The control method of a semiconductor device as claimed in claim 10, wherein
the second fuse determining operation is performed at least twice,
a first one of the second fuse determining operation is performed simultaneously with the first fuse determining operation, and thereafter a second one of the second fuse determining operation is performed.

12. The control method of a semiconductor device as claimed in claim 10, wherein
each of the first and second fuse determining operations is performed at least twice,
a first one of the second fuse determining operation is performed simultaneously with a first one of the first fuse determining operation, and thereafter a second one of the second fuse determining operation is performed simultaneously with a second one of the first fuse determining operation.
